(19) United States
(12) Patent Application Publication
(10) Pub. No.: US 2024/0175135 A1
(43) Pub. Date: May 30, 2024

(54) METAL ORGANIC CHEMICAL VAPOR DEPOSITION APPARATUS

(71) Applicant: TES CO., LTD, Yongin-si, Gyeonggi-do (KR)

(72) Inventors: Sung-Chul CHOI, Yongin-si, Gyeonggi-do (KR); Kwang-Il CHO, Yongin-si, Gyeonggi-do (KR)

(73) Assignee: TES CO., LTD, Yongin-Si, Gyeonggi-do (KR)

(21) Appl. No.: 18/283,810

(22) PCT Filed: Mar. 27, 2022
(86) PCT No.: PCT/KR2022/004278

§ 371 Date: Sep. 24, 2023

(30) Foreign Application Priority Data
Mar. 30, 2021 (KR) 10-2021-0040792

(51) Int. Cl. C23C 16/458; C23C 16/18; C23C 16/46

(52) U.S. Cl. CPC C23C 16/4586; C23C 16/18; C23C 16/463

(57) ABSTRACT

The present disclosure relates to a metal organic chemical vapor deposition apparatus, and more particularly to a metal organic chemical vapor deposition apparatus in which a coil connector through which a coil extension of a heating coil passes is provided in a chamber to improve assemblability and ease of maintenance by disposing, outside the chamber, a connector connecting a feedthrough and the heating coil for heating a substrate.

### BACKGROUND

### Technical Field

The present disclosure relates to a metal organic chemical vapor deposition apparatus, and more particularly to a metal organic chemical vapor deposition apparatus in which a coil connector through which a coil extension of a heating coil passes is provided in a chamber to improve assemblability and ease of maintenance by disposing, outside the chamber, a connector connecting a feedthrough and the heating coil for heating a substrate.

### Description of the Related Art

A metal organic chemical vapor deposition (MOCVD) apparatus supplies a mixed gas of a group 3 alkyl (organic metal raw material gas) and a group 5 reaction gas with a high-purity carrier gas into a reaction chamber and thermally decomposes the mixed gas on a heated substrate to grow a compound semiconductor crystal. The MOCVD apparatus includes a susceptor mounted on a substrate and injects gas from a side surface to grow a semiconductor crystal on the substrate.

The MOCVD apparatus includes the heating coil for heating the substrate and supplies RF power and cooling water to the heating coil by the feedthrough outside the chamber. Thus, a component of a connector connecting the feedthrough and the heating coil is necessary.

In the case of a MOCVD apparatus according to the related art, the connector between the feedthrough and the heating coil is disposed inside the chamber. In this case, the assemblability of the feedthrough and heating coil is improved, but when a leak occurs at the connector due to repeated thermal expansion and contraction under a high-temperature environment inside the chamber, if a high-pressure cooling fluid leaks, components inside the chamber may be damaged, and there is an inconvenience of having to disassemble the chamber again for maintenance.

In the case of the MOCVD apparatus according to the related art, a ceramic material is used for insulation from a metal gasket. In this case, welding is performed to join ceramics and metals, and welding of ceramics and metals is a very difficult technique and requires a lot of time and money for manufacturing and assembly.

### SUMMARY

### Technical Problem

The present disclosure is to resolve this problem and to provide a metal organic chemical vapor deposition apparatus for connection with the outside of a chamber when a feedthrough and a heating coil are connected.

An object of the present disclosure is to provide a metal organic chemical vapor deposition apparatus including a relatively compact coil connector with improved assemblability when a coil extension of a heating coil provides a coil connector to be disposed through a chamber.

### Technical Solution

To achieve the above object of the present disclosure, provided is a metal organic chemical vapor deposition apparatus including a chamber providing a processing space in which a substrate is processed, a gas supply configured to supply a process gas toward the substrate inside the chamber, a substrate support that is disposed inside the chamber and on which the substrate is accommodated, a heating coil disposed on a side surface of the substrate support and configured to heat the substrate support, a coil extension connected to the heating coil and constituting a supply path through which RF power and cooling water are supplied to the heating coil, and a coil connector disposed in the chamber to allow the coil extension to pass therethrough and configured to insulate the chamber from the coil extension.

The coil connector may include a connection flange disposed on a side wall of the chamber and including a first through hole formed therein, through which the coil extension passes, an insulation block disposed on a first surface of the connection flange and including a second through hole formed therein, through which the coil extension passes, and an additional block disposed on a first surface of the insulation block, including a third through hole formed therein, through which the coil extension passes, and including an O-ring sealing the coil extension.

The metal organic chemical vapor deposition apparatus may further include an O-ring pressurizer configured to pressurize the O-ring.

The metal organic chemical vapor deposition apparatus may further include an O-ring cap disposed on a first surface of the additional block on which the O-ring pressurizer is mounted.

The connection flange may further include a cooling flow passage.

An end of the coil extension may be disposed outside the chamber, and the metal organic chemical vapor deposition apparatus may further include a connector configured to connect an end of the coil extension with a feedthrough configured to supply RF power and cooling water to the heating coil from an outside of the chamber.

The metal organic chemical vapor deposition apparatus may further include an insulation part disposed through the connection flange and the insulation block and surrounding a portion of the coil extension inside the chamber.

### Advantageous Effects

According to the present disclosure having the above-described configuration, the feedthrough and the heating coil are connected to each other outside the chamber, and thus even when leakage occurs, repairs may be made quickly and easily without damaging components inside the chamber.

The present disclosure may provide a relatively compact coil connector with improved assemblability, which allows a coil extension of a heating coil to pass through a chamber.

### BRIEF DESCRIPTION OF THE DRAWING FIGURES

FIG. 1 is a side view of a metal organic chemical vapor deposition apparatus according to an embodiment of the present disclosure.

FIG. 2 is a perspective view showing a first heating coil and a coil connector.

FIG. 3 is an exploded perspective view of the coil connector in FIG. 2.

FIG. 4 is a perspective view showing an O-ring cap, an additional block, and an O-ring pressurizer.

FIG. 5 is a side cross-sectional view of a case in which a coil connector is formed on a side wall of a chamber.

FIG. 6 is a partially enlarged view of FIG. 5.

### DETAILED DESCRIPTION OF THE EXEMPLARY EMBODIMENTS

Hereinafter, a metal organic chemical vapor deposition apparatus according to embodiments of the present disclosure will be described in detail with reference to the drawings.

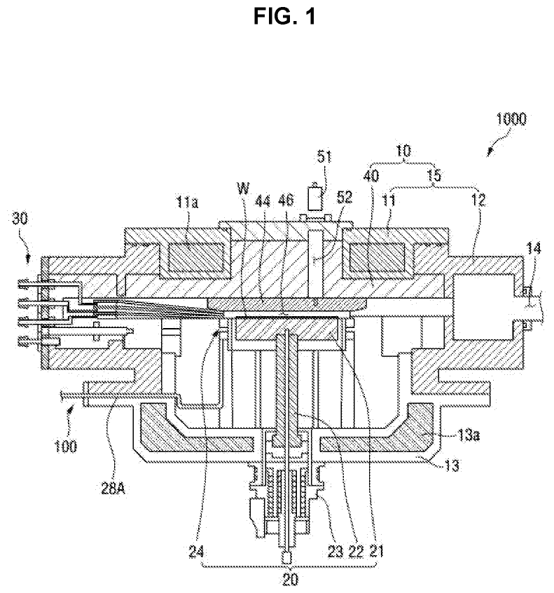

FIG. 1 is a cross-sectional view of a structure of a metal organic chemical vapor deposition apparatus 1000 according to an embodiment of the present disclosure.

Referring to FIG. 1, the metal organic chemical vapor deposition apparatus 1000 includes a chamber 10, a substrate support 20, and a gas supply 30.

The chamber 10 may include an outer chamber 15 and an inner chamber 40 that provides a processing space 46 for processing a substrate W within the outer chamber 15.

The outer chamber 15 includes a chamber lid 11 covering the top, an external wall part 12 fastened to the chamber lid 11 and covering a side of the chamber, and a bottom flange part forming a bottom surface of the chamber. 13.

The chamber lid 11 may be detachably fastened to the external wall part 12 through a fastening element such as a bolt, and a cooling flow passage 11a may be formed in the chamber lid 11. A cooling medium such as cooling water or cooling gas flows through the cooling flow passage 11a to cool the chamber 10 heated by high-temperature heat generated in a deposition process in the chamber 10.

A sensor tube 52 serving as a light measuring passage for an optical sensor 51 for optically measuring a thin film deposited on the substrate W within the inner chamber 40 may be installed in the chamber lid 11. The sensor tube 52 may be disposed through the chamber lid 11 and the inner chamber 40. Here, a purge gas may be introduced into the sensor tube 52 to prevent reaction gas from being discharged from the inner chamber 40 to the sensor tube 52.

The external wall part 12 is fastened to the chamber lid 11 and is configured to cover the side of the inner chamber 40. A vent hole 14 is formed in the external wall part 12, and the vent hole 14 is connected to a gas exhaust line (not shown) to discharge the reaction gas remaining in the processing space 46 after the deposition process is completed to the outside of the chamber 10 through the vent hole 14 and the gas exhaust line (not shown).

The bottom flange part 13 is provided below the outer chamber 15. A cooling flow passage 13a may be formed in the bottom flange part 13. A cooling medium such as cooling water or cooling gas flows through the cooling flow passage 13a to cool the chamber 10 heated by high-temperature heat generated in the deposition process in the inner chamber 40.

The substrate support 20 on which the substrate W is accommodated may be disposed inside the inner chamber 40. The substrate support 20 includes a heating coil 24 for heating the substrate W. For example, the substrate support 20 includes a heater block 21 on which the substrate W is accommodated and heated, a shaft 22 that supports and rotates the heater block 21, a sealing part 23, and the heating coil 24 for heating the substrate W by induction-heating the heater block 21. In this case, the heating coil 24 may be configured to heat a side surface of the heater block 21.

A barrier lid 44 is provided above the substrate support 20. A space between the barrier lid 44 and the heater block 21 corresponds to the processing space 46. A process gas supplied from the gas supply 30 described above may be supplied to the substrate W in the processing space 46. Among the process gases, gases that do not participate in the reaction are discharged to the outside of the chamber 10 through the vent hole 14 and the gas exhaust line (not shown).

A distance between the barrier lid 44 and the heater block 21 is an important factor for smooth processing of the substrate W, and thus may be determined in advance. In this case, since it is not easy to adjust the height of the inner chamber 40 to which the barrier lid 44 is connected, the thickness of the barrier lid 44 may be adjusted to adjust the distance between the barrier lid 44 and the heater block 21.

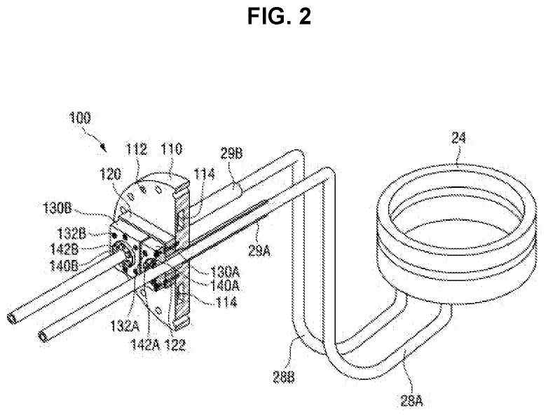

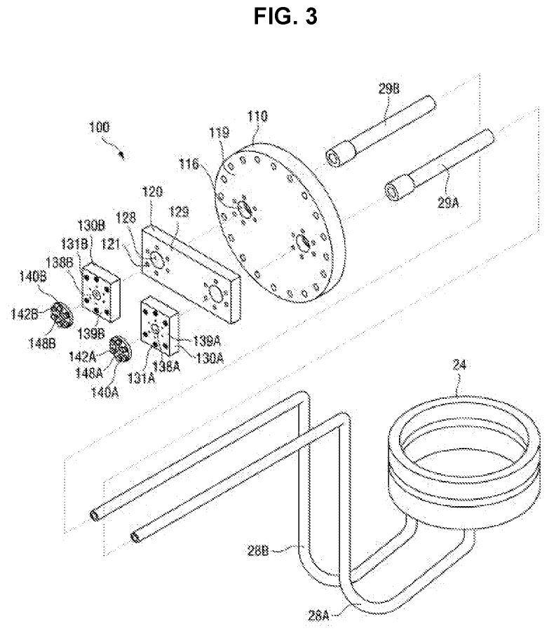

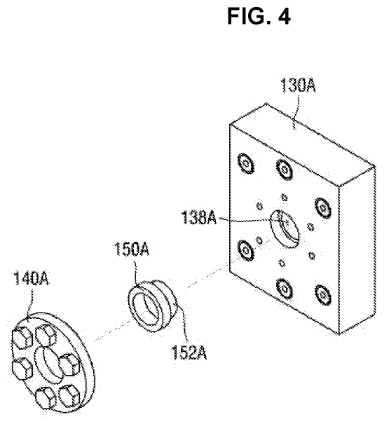

FIG. 2 is a perspective view showing the heating coil 24 and a coil connector 100. FIG. 3 is an exploded perspective view of the coil connector 100 in FIG. 2. FIG. 4 is a perspective view showing an O-ring cap 140A, an additional block 130A, and an O-ring pressurizer 150A.

Referring to FIGS. 2 to 4, the heating coil 24 is located on the side surface of the heater block 21 to induction-heat the heater block 21. Coil extensions 28A and 28B connected to the heating coil 24 and constituting a supply path through which RF power and cooling water are supplied to the heating coil 24 may be provided.

The heating coil 24 is located on the side surface of the heater block 21 in the substrate support 20 to induction-heat the heater block 21 from the side. A shape of the heating coil 24 is not limited and may be modified into a shape suitable for heating the heater block 21.

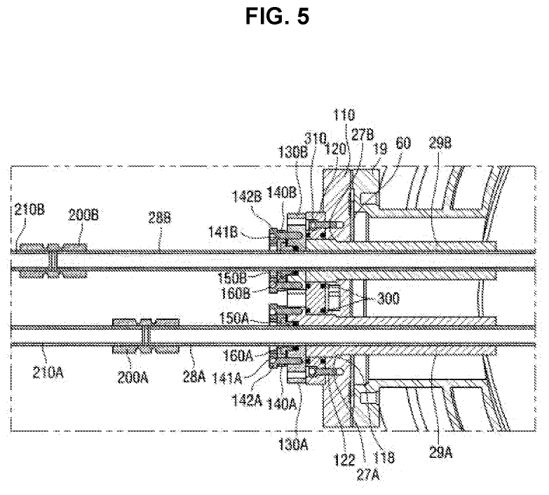

The coil extensions 28A and 28B may extend from the heating coil 24 and are connected to feedthroughs 210A and 210B (refer to FIG. 5) described below to supply RF power and cooling water to the heating coil 24. A pair of the coil extensions 28A and 28B may be provided and connected to the heating coil 24.

For example, the coil extensions 28A and 28B may include a first coil extension 28A and a second coil extension 28B and may each be connected to the heating coil 24. In this case, cooling water may be supplied to the heating coil 24 through the first coil extension 28A, and cooling water may be discharged from the heating coil 24 through the second coil extension 28B, and vice versa.

The feedthroughs 210A and 210B for supplying cooling water and RF power to the heating coil 24 are connected to the coil extensions 28A and 28B described above, and cooling water and RF power are supplied to the heating coil 24 through the feedthroughs 210A and 210B, and the coil extensions 28A and 28B.

In this case, an end of the feedthroughs 210A and 210B and an end of the coil extensions 28A and 28B are connected to each other using connectors 200A and 200B (refer to FIG. 5).

In the case of the metal organic chemical vapor deposition apparatus according to the related art, the aforementioned connector is disposed inside the chamber. In the metal organic chemical vapor deposition apparatus according to the related art, the connector is disposed inside the chamber to separate the heating coil from the feedthrough when replacing or maintaining the heating coil. Thus, in the case of the metal organic chemical vapor deposition apparatus according to the related art, the feedthrough passes through a flange of the coil connector, and one end is placed outside the chamber and the other end is placed inside the chamber. This feedthrough is welded to the flange of the coil connector for sealing the inside of the chamber and is a non-separable structure.

That is, in the related art, the coil extensions 28A and 28B and the feedthroughs 210A and 210B are connected to each other inside the chamber 10. While the configuration according to the related art has an aspect of convenient assembly, there is an inconvenience in that components inside the chamber 10 are damaged and the chamber 10 needs to be disassembled and repaired in the event of water leakage from the connector.

In the present disclosure, in order to resolve this problem, the connectors 200A and 200B connecting the coil extensions 28A and 28B and the feedthroughs 210A and 210B are disposed outside the chamber 10. That is, even if water leakage occurs in the connectors 200A and 200B, components inside the chamber 10 may be protected, and furthermore, maintenance may be performed conveniently and quickly by connecting the feedthroughs 210A and 210B and the coil extensions 28A and 28B to the connectors 200A and 200B from the outside of the chamber 10.

As in the present disclosure, when the connectors 200A and 200B are disposed outside the chamber 10, the coil extensions 28A and 28B need to pass through the chamber 10, and thus the coil connector 100 that is disposed on a side wall and through which the coil extensions 28A and 28B pass may be provided.

The coil connector 100 may insulate between the coil extensions 28A and 28B and the chamber 10 and may simultaneously maintain a vacuum inside the chamber 10.

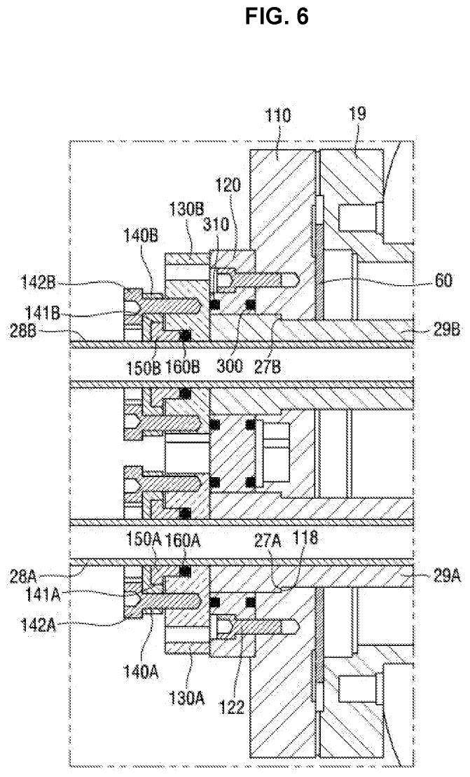

FIG. 5 is a cross-sectional view of a case in which the aforementioned coil connector 100 is mounted on a chamber flange 19 formed on a side wall of the chamber 10, and FIG. 6 is a partially enlarged view of FIG. 5.

Referring to FIGS. 3 to 6, the coil connector 100 may include a connection flange 110 disposed on a side wall of the chamber 10 and including a first through hole 116 formed therein, through which the coil extensions 28A and 28B pass, an insulation block 120 disposed on a first surface 119 of the connection flange 110 and including a second through hole 128 formed therein, through which the coil extensions 28A and 28B pass, and additional blocks 130A and 130B disposed on a first surface 129 of the insulation block 120, including third through holes 138A and 138B formed therein, through which the coil extensions 28A and 28B pass, and including an O-ring for sealing the coil extensions 28A and 28B.

A first fastening hole 112 is formed in the connection flange 110 and is fastened and fixed to the forementioned chamber 10 by a bolt. In this case, a gasket 60 may be provided for sealing a space between the connection flange 110 and the chamber flange 19.

The first through holes 116 corresponding to the number of the coil extensions 28A and 28B is formed at approximately the center of the connection flange 110, and the coil extensions 28A and 28B pass through the first through hole 116 and extend to the outside of the chamber 10.

A cooling flow passage 114 may be further formed in the connection flange 110. A cooling fluid such as water may flow through the cooling flow passage 114 to lower the temperature of the coil connector 100, thereby preventing leakage due to thermal expansion of the coil extensions 28A and 28B.

The insulation block 120 may be connected to the first surface 119 of the connection flange 110. All of the insulation block 120, the additional blocks 130A and 130B, O-ring caps 140A and 140B, and bolts for fastening these may be made of an insulation material to insulate between the coil extensions 28A and 28B and the chamber 10.

The insulation block 120, the additional blocks 130A and 130B, the O-ring caps 140A and 140B, and bolts for fastening these may be made of an engineering plastic or super engineering plastic material. For example, the insulation block 120, the additional blocks 130A and 130B, the O-ring caps 140A and 140B, and bolts for fastening these may be made of any one or a combination of two or more selected from the group consisting of polysulfone (PSU), polyarylate (PAR), polyetherimide (PEI), polyethersulfone (PES), polyphenylenesulfone (PPS), polyimide (PI), teflon (PTFE), and polyetheretherketone (PEEK).

A first surface 19 of the connection flange 110 may be formed as a surface facing the outside of the chamber 10. Accordingly, the insulation block 120 may be fixed to the first surface 19 facing the outside of the connection flange 110. In this case, a second fastening hole 121 is formed in the insulation block 120 and is fastened and fixed to the first surface 19 of the connection flange 110 with a bolt 122. The insulation block 120 may be configured as a separate member corresponding to the number of the coil extensions 28A and 28B, or as a single member as shown in the drawing.

The second through hole 128 may be formed in the insulation block 120, and the coil extensions 28A and 28B may pass through the second through hole 128 to extend to the outside of the chamber 10.

The additional blocks 130A and 130B may be connected to the first surface 129 of the insulation block 120, that is, the first surface 129 facing the outside of the chamber 10. Third fastening holes 131A and 131B may be formed in the additional blocks 130A and 130B and fastened and fixed to the first surface 129 of the insulation block 120 by bolts 132A and 132B. The additional blocks 130A and 130B seal ends of the insulation parts 29A and 29B surrounding the coil extensions 28A and 28B.

In detail, the insulation parts 29A and 29B are provided to surround the coil extensions 28A and 28B inside the chamber 10 and are disposed adjacent to the coil connector 100 in the coil extensions 28A and 28B.

When the insulation parts 29A and 29B are not provided, arcing may occur between a pair of the coil extensions 28A and 28B or between the coil extensions 28A and 28B and the connection flange 110. The insulation parts 29A and 29B may be disposed through the connection flange 110 and the insulation block 120. The insulation parts 29A and 29B may be made of, for example, a ceramic material, and the insulation material is not particularly limited.

To install the insulation parts 29A and 29B, the insulation parts 29A and 29B is installed by connecting the connection flange 110 to the chamber flange 19, and then inserting the insulation parts 29A and 29B into the first through hole 116 of the connection flange 110 to pass therethrough in a direction from the outside to the inside of the chamber 10.

At this time, to match a length by which the insulation parts 29A and 29B are inserted into the chamber 10 or a length by which the insulation parts 29A and 29B protrude into the chamber 10, first staircases 27A and 27B may be formed on the insulation parts 29A and 29B, and furthermore, a second staircase 118 corresponding to the first staircases 27A and 27B may be formed on an inner circumference of the first through hole 116 of the connection flange 110.

Thus, when the insulation parts 29A and 29B are inserted into the first through hole 116 of the connection flange 110, the first staircases 27A and 27B may come into contact with the second staircase 118 to determine an insertion length or a protrusion length of the insulation parts 29A and 29B.

According to the present disclosure, as described above, the connectors 200A and 200B connecting the coil extensions 28A and 28B and the feedthroughs 210A and 210B to each other are disposed outside the chamber 10. As a result, an insulation effect may be increased by extending the lengths of the insulation parts 29A and 29B towards the inside of the chamber 10 compared with the case in which a connector connecting the coil extensions 28A and 28B and the feedthroughs 210A and 210B is disposed inside a chamber like in the related art.

An inner diameter of the first through hole 116 formed in the insulation block 120 may correspond to or be slightly larger than an outer diameter of each of the insulation parts 29A and 29B larger than an outer diameter of each of the coil extensions 28A and 28B.

After the insulation parts 29A and 29B are inserted, the additional blocks 130A and 130B may be connected to the first surface 129 of the insulation block 120 to seal ends of the insulation parts 29A and 29B and to prevent the insulation parts 29A and 29B from being exposed to the outside.

As described above, when the insulation block 120 is connected to the first surface 119 of the connection flange 110 and the additional blocks 130A and 130B are connected to the first surface 129 of the insulation block 120, a sealing member may be provided to seal the inside of the chamber 10.

For example, the sealing member may include an O-ring or the like and may include a first O-ring 300 between the connection flange 110 and the insulation block 120, a second O-ring 310 between the insulation block 120 and the additional blocks 130A and 130B, and third O-rings 160A and 160B of the additional blocks 130A and 130B.

The first O-ring 300 may be pressurized between the connection flange 110 and the insulation block 120, and the second O-ring 310 may be pressurized and sealed between the insulation block 120 and the additional blocks 130A and 130B. In the case of the third O-rings 160A and 160B, O-ring pressurizers 150A and 150B may be provided to pressurize the third O-rings 160A and 160B and to seal a space between the additional blocks 130A and 130B and the O-ring pressurizers 150A and 150B. In this case, the third O-rings 160A and 160B may be configured as a so-called ‘ultra-torr seal’.

For example, as shown in FIG. 4, the O-ring pressurizer 150A includes an O-ring pressurizing protrusion 152A. The third O-ring 160A may be pressurized by the O-ring pressurizing protrusion 152A. Among the O-ring pressurizers, the other O-ring pressurizers may have the same configurations, and repeated descriptions are omitted.

To pressurize the third O-rings 160A and 160B by the O-ring pressurizers 150A and 150B, the O-ring caps 140A and 140B may be further provided on first surfaces 139A and 139B of the additional blocks 130A and 130B. Fourth through holes 148A and 148B may be formed in the O-ring caps 140A and 140B to allow the coil extensions 28A and 28B to pass through fourth through holes 148A and 148B.

That is, the O-ring caps 140A and 140B are fastened and fixed to the first surfaces 139A and 139B of the additional blocks 130A and 130B by bolts 142A and 142B.

For example, insertion grooves 141A and 141B into which the O-ring pressurizers 150A and 150B are inserted may be formed on a surface of the O-ring caps 140A and 140B, which faces the chamber 10. Thus, in a state in which the O-ring pressurizers 150A and 150B are disposed, when the O-ring caps 140A and 140B are connected to the additional blocks 130A and 130B, the O-ring pressurizers 150A and 150B may be pressurized by the O-ring caps 140A and 140B in a state in which the O-ring pressurizers 150A and 150B are partially inserted into the insertion grooves 141A and 141B. In this case, a degree of sealing may be adjusted by adjusting a pressure applied to the third O-rings 160A and 160B by the O-ring pressurizers 150A and 150B depending on the strength for fastening the O-ring caps 140A and 140B.

As shown in the drawing, the O-ring pressurizers 150A and 150B may be configured as a separate member from the O-ring caps 140A and 140B or the O-ring pressurizers 150A and 150B may also be integrally formed with the O-ring caps 140A and 140B to configure one member.

When the coil connector 100 includes the aforementioned components, the coil extensions 28A and 28B pass through the coil connector 100 and extend to the outside of the chamber 10 as shown in FIG. 5. An end of each of the coil extensions 28A and 28B may be inserted into and connected to one end of each of the connectors 200A and 200B, and an end of each of the feedthroughs 210A and 210B may be inserted into and connected to the other end of each of the connectors 200A and 200B.

As such, the connectors 200A and 200B connecting the coil extensions 28A and 28B and the feedthroughs 210A and 210B are disposed outside the chamber 10, and thus even when leakage occurs in the connectors 200A and 200B, components inside the chamber 10 may be protected, and maintenance may be performed conveniently and quickly.

When the heating coil 24 is separated, the heating coil 24 may be separated from the inside of the chamber by separating the connectors 200A and 200B outside the chamber 10, separating the O-ring caps 140A and 140B, and then pulling the coil extensions 28A and 28B in a direction from the coil connector 100 to the inside of the chamber 10.

While the present disclosure has been described referring to the exemplary embodiments of the present disclosure, those skilled in the art will appreciate that many modifications and changes can be made to the present disclosure without departing from the spirit and essential characteristics of the present disclosure. Therefore, if the modifications basically include the elements of the claims of the present disclosure, all of them are considered to be included in the technical scope of the present disclosure.

What is claimed is:

1. A metal organic chemical vapor deposition apparatus comprising:
a chamber providing a processing space in which a substrate is processed;
a gas supply configured to supply a process gas toward the substrate inside the chamber;
a substrate support that is disposed inside the chamber and on which the substrate is accommodated;
a heating coil disposed on a side surface of the substrate support and configured to heat the substrate support;
a coil extension connected to the heating coil and constituting a supply path through which RF power and cooling water are supplied to the heating coil; and
a coil connector disposed in the chamber to allow the coil extension to pass therethrough and configured to insulate the chamber from the coil extension.

2. The metal organic chemical vapor deposition apparatus of claim 1, wherein the coil connector includes:
a connection flange disposed on a side wall of the chamber and including a first through hole formed therein, through which the coil extension passes;
an insulation block disposed on a first surface of the connection flange and including a second through hole formed therein, through which the coil extension passes; and
an additional block disposed on a first surface of the insulation block, including a third through hole formed therein, through which the coil extension passes, and including an O-ring sealing the coil extension.

3. The metal organic chemical vapor deposition apparatus of claim 2, further comprising an O-ring pressurizer configured to pressurize the O-ring.

4. The metal organic chemical vapor deposition apparatus of claim 3, further comprising an O-ring cap disposed on a first surface of the additional block on which the O-ring pressurizer is mounted.

5. The metal organic chemical vapor deposition apparatus of claim 2, wherein the connection flange further includes a cooling flow passage.

6. The metal organic chemical vapor deposition apparatus of claim 1, wherein an end of the coil extension is disposed outside the chamber; and
wherein the metal organic chemical vapor deposition apparatus further includes a connector configured to connect the end of the coil extension with a feedthrough configured to supply RF power and cooling water to the heating coil from an outside of the chamber.

7. The metal organic chemical vapor deposition apparatus of claim 2, further comprising an insulation part disposed through the connection flange and the insulation block and surrounding a portion of the coil extension inside the chamber.
